(19) United States
(12) Patent Application Publication
(10) Pub. No.: US 2018/0223431 A1
(43) Pub. Date: Aug. 9, 2018

(54) FILM-FORMING METHOD

(71) Applicant: PHILTECH, Inc., Tokyo (JP)

(72) Inventors: Yuji FURUMURA, Kanagawa (JP); Noriyoshi SHIMIZU, Tokyo (JP); Shinji NISHIHARA, Tokyo (JP); Eri HAIKATA, Tokyo (JP)

(21) Appl. No.: 15/949,410

(22) Filed: Apr. 10, 2018

Related U.S. Application Data
(63) Continuation of application No. 15/298,703, filed on Oct. 20, 2016.

(30) Foreign Application Priority Data
Nov. 30, 2015 (JP) 2015233794

(51) Int. Cl. C23C 16/46; C23C 16/455; C23C 16/02; H01L 51/52; C23C 16/54; C23C 16/452; C08J 7/04; H01L 51/56

(52) U.S. Cl. CPC C23C 16/46; C23C 16/45523; C23C 16/0272; H01L 51/5253; H01L 51/56; C23C 16/455; C23C 16/452; C08J 7/04; C23C 16/545

(57) ABSTRACT

Source gases are instantaneously heated, at least two kinds of generated gas molecular species generated by instantaneously heating the source gases are independently introduced and brought into contact with a substrate having a temperature lower than heating temperature of the instantaneously-heating mechanism for source gas to form a first compound film and to form a second compound film containing at least one element of elements contained in the first compound film, and a multilayer film composed of at least the first compound film and the second compound film is produced.

### TECHNICAL FIELD

The present invention relates to a film-forming method.

### BACKGROUND ART

In general, as most of chemical bond energies of molecules in a gas are 3 eV or more, the molecules are not decomposed when the gas is merely heated to a high temperature. However, when a gas heated to a high temperature is caused to vertically collide with a metal containing an element having a catalytic effect, the gas molecules structurally change. When a chemically reactive gas is heated and caused to collide with a catalyst, a gas including molecular species different from those of the original gas or having a form different from that of the original gas will be produced (to be referred to as a catalyst collision reaction hereinafter).

For example, when, in a vessel containing a ruthenium catalyst, a gas obtained by instantaneously heating methane and water vapor is caused to collide with the ruthenium catalyst, the reaction proceeds to generate hydrogen H₂, carbon dioxide CO₂, and carbon monoxide CO. This reaction is one example of a catalyst collision reaction.

For example, water is heated to be vaporized. This is considered to be caused by not only a simply increase in temperature but also a structural change from polymers (clusters of water) obtained by polymerizing molecules to monomers. The generated monomer gas is estimated to be changed in chemical characteristic and to have an active chemical characteristic different from that of normal water.

In order to industrially use the catalyst collision reaction, an apparatus for instantaneously heating a gas (heating mechanism) and a low-price compact heating apparatus for causing a gas to collide with a catalyst are required.

A gas heating device which satisfies the requests is described in Japanese Patent No. 5105620 (Patent Document 1). The instantaneously-heating devices described in the patent document is called a heat beam heating device here. This heating principle is to cause a gas to collide with a high-temperature wall at a high speed to efficiently perform heat exchange between the wall and the gas.

For this purpose, the speed of a gas is increased in a narrow gas flow path formed on a surface of a heat exchange substrate, and the gas is caused to vertically collide with a flow path wall. This flow path wall is electrically heated, and heat exchange is caused by this collision.

The invention of Japanese Patent No. 5105620 discloses a basic invention of a film-forming apparatus that heats a plurality of gases with the heat beam heating device to form a film of a material, which is normally considered not to be able to be grown without heating a substrate to a temperature higher than the endurable temperature of a glass or plastic substrate, on those substrates which are kept at a temperature lower than the heating temperature of the heat beam heating device.

More specifically, when a film can be formed at room temperature, a ceramic film typified by an alumina film, a silicon oxide film, and a silicon nitride film or a film of a refractory metal compound typified by titanium nitride or titanium oxide can be formed on a plastic film substrate.

### CITATION LIST

### Summary of Invention

A technique that introduces gas molecular species generated by heating a source gas to a room-temperature substance to form a film is described in Japanese Patent No. 5105620. In this technique, as a material which film is considered not to be able to be formed at a temperature equal to or lower than the endurable temperature of the substance, an aluminum oxide or nitride film, a titanium oxide or nitride film, and a silicon oxide or nitride film are given. Such materials are called high-temperature materials hereinafter.

Here, a method of heating a source gas to generate active gas molecular species and introducing the active gas molecular species to a substrate surface to form a film of a high-temperature material on a plastic substrate is considered as an example. In this example, when a substrate is transformed after the film is formed, a new issue may occur. That is, even though the plastic substrate itself is transformed, the substrate is not cracked because the substrate is made of a plastic. However, the high-temperature material may be cracked by being transformed at a certain level or higher, or the material may be disadvantageously peeled from the substrate by being transformed at a certain level or higher.

More specifically, even though a film of a high-temperature material can be formed on a surface of a plastic substrate, when the substrate is transformed at a certain level or higher, the film may be cracked or peeled to pose a practical issue.

Thus, the present invention has been made in consideration of the above issue to provide a film-forming apparatus in which, when a source material is instantaneously heated and a generated desired gas is introduced onto a substrate surface kept at a low temperature to form a film of a high-temperature material, a substrate which does not allow to crack or peel the high-temperature material film even though the substrate is transformed is produced.

At least one embodiment of the present invention provides the following items to solve the above issue.

### Embodiment (1)

One or more embodiments of the present invention provide a film-forming method using a film-forming apparatus providing a plurality of heating mechanisms, each heating mechanism including a flow path defined by a flow path wall in which a source gas collides with the flow path wall to heat the source gas by heat exchange between the source gas and the flow path wall, thereby generating chemically active gas molecular species, and a gas outlet connected to a guide through a pipe. The method includes the steps of: introducing at least two kinds of the gas molecular species generated by heating by the plurality of heating mechanisms independently and blowing out at least two kinds of the gas molecular species through the guides to bring into contact with a substrate kept at a temperature lower than a heating temperature of the heating mechanisms to form a first compound film; and forming a second compound film containing at least one element of elements contained in the first compound film on the first compound film to form a multilayer film including at least the first compound film and the second compound film on the substrate.

### Embodiment (2)

One or more embodiments provide the film-forming method wherein the heating mechanism includes the flow path wall made of a metal material containing an element having a catalytic function.

### Embodiment (3)

One or more embodiments provide the film-forming method wherein the first compound film and the second compound film are compound films containing at least one of elements including hydrogen, oxygen, nitrogen, carbon, silicon, aluminum, gallium, titanium, zinc, indium, and magnesium.

### Embodiment (4)

One or more embodiments provide the film-forming method wherein the first compound film and the second compound film are formed while a temperature of the heating mechanism is changed within a set temperature range.

### Embodiment (5)

One or more embodiments provide the film-forming method wherein the flow path wall of the heating mechanism is made of a metal containing at least one of elements including ruthenium, nickel, platinum, iron, chromium, aluminum, and tantalum.

### Embodiment (6)

One or more embodiments provide the film-forming method wherein the heating temperature of the heating mechanism ranges from room temperature to 900° C.

### Embodiment (7)

One or more embodiments provide the film-forming method wherein the substrate moves.

### Embodiment (8)

One or more embodiments provide the film-forming method wherein a material of the substrate on which the multilayer film is formed is at least one of materials including glass, silicon wafer, plastic, and carbon.

### Embodiment (9)

One or more embodiments provide the film-forming method wherein the substrate is an organic EL device, a liquid crystal device, a solar battery, or a device substrate on which patterns are formed.

According to one or more embodiments of the present invention can advantageously generate a substrate from which, when a source gas is instantaneously heated and a generated desired gas is introduced onto a substrate surface kept at a low temperature to form a film of a high-temperature material, the high-temperature material film is not cracked or peeled even though the substrate is transformed.

### BRIEF DESCRIPTION OF DRAWINGS

FIG. 1 is a block diagram of a film-forming apparatus according to the embodiment.

FIG. 2 is a block diagram of a film-forming apparatus according to a modification of the embodiment.

FIG. 3 is a schematic diagram of an instantaneously-heating mechanism according to the embodiment.

FIG. 4 is a schematic diagram of a section of a multilayer film according to the embodiment.

### DETAILED DESCRIPTION

### Embodiment

An embodiment of the present invention will be described below.

A film-forming apparatus according to the embodiment, when a source gas is caused to flow in an instantaneously-heating mechanism for source gas which instantaneously heats the source gas to a temperature higher than that of a substrate and at least two kinds of generated gas molecular species are introduced to a substrate surface and brought into contact with the substrate surface to grow a compound film, produces a multilayer film in which an intermediate layer is formed between the film and the substrate.

More specifically, the film-forming apparatus according to the embodiment heats the source gas to a high temperature to change a molecular structure of the source gas and to generate chemically active molecular species, introduces the active molecular species reacting with each other to the substrate surface and brings the active molecular species into contact with the substrate surface to grow a multilayer film on a surface of the substrate kept at a temperature lower than a temperature of the instantaneously-heating mechanism for source gas.

### <Configuration of Film-Forming Apparatus>

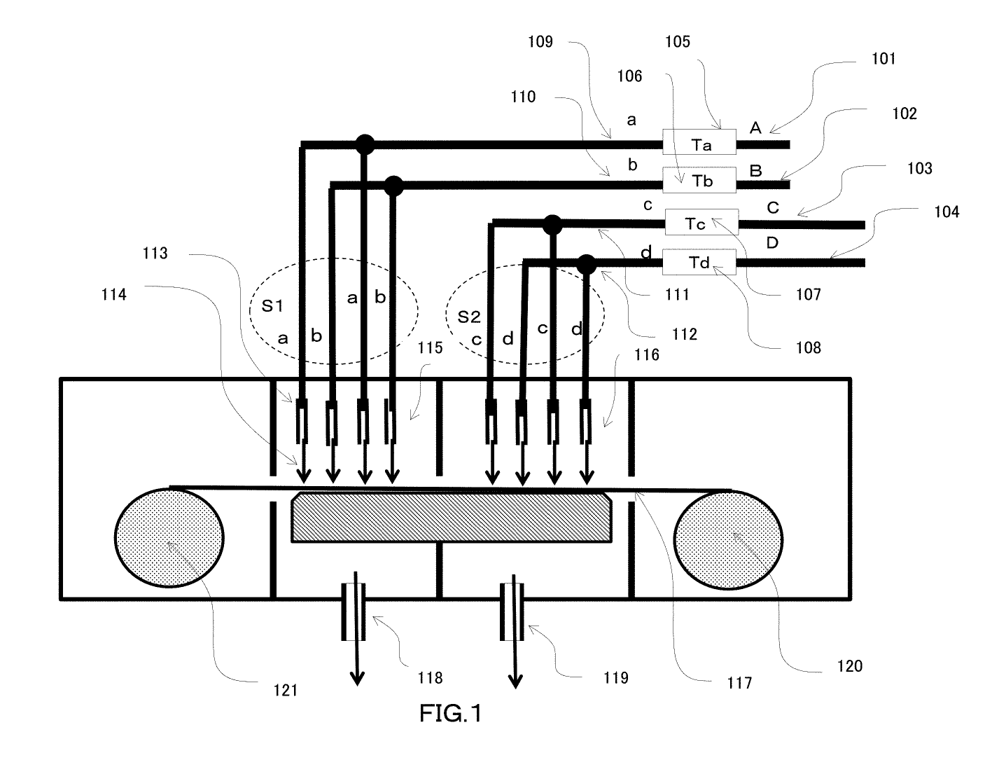

A configuration of the film-forming apparatus according to the embodiment will be described below with reference to FIG. 1.

As shown in FIG. 1, the film-forming apparatus according to the embodiment including a gas instantaneously-heating mechanisms 105, 106, 107, and 108, a guide 113, film-forming chambers 115 and 116, a film-shaped substrate 117, exhaust ports 118 and 119, a rewinding drum 120, a supply drum 121, and reaction sets S1 and S2.

The gas instantaneously-heating mechanisms 105, 106, 107, and 108 take in source gases A (101), B (102), C (103), and D (104) of which the flow rates are time-controlled, instantaneously heat the source gases at temperatures Ta, Tb, Tc, and Td to emit generated gases a, b, c, and d (109, 110, 111, and 112).

The guide 113 is a mechanism which introduces generated gases a, b, c, and d (109, 110, 111, and 112) emitted in the gas instantaneously-heating mechanisms 105, 106, 107, and 108 to the film-forming chambers 115 and 116 to spray the gases on a surface of the film-shaped substrates 117 placed in the film-forming chambers 115 and 116. The plurality of guides 113 are prepared for each of the source gases.

The exhaust ports 118 and 119 ventilate the generated gases a, b, c, and d (109, 110, 111, and 112) sprayed on the surface of the film-shaped substrate 117. The film-shaped substrate 117 are winded on the rewinding drum 120 and the supply drum 121. When FIG. 1 is taken as an example, upon completion of the film-forming step by the generated gases a and b, the rewinding drum 120 and the supply drum 121 rotate to feed the film-shaped substrate 117, the film-forming step by the generated gases c and d are executed on a film formed by the generated gases a and b, and the film-shaped substrate 117 which has gone through the above steps is collected with the rotation of the rewinding drum 120. In the film-forming apparatus according to the embodiment, a plurality of reaction sets S1 and S2 are prepared to form a multilayer film on the film-shaped substrate 117.

For example, in the embodiment, the two reaction sets of generated gas for the generated gases a and b and the generated gases c and d are defined as the S1 and S2, respectively, and prepared. More specifically, a required number of reaction sets for generated gas are prepared depending on the number of kinds of multilayer films. The embodiment shows a film-forming apparatus having a structure in which film-forming apparatuses are installed in series with each other to grow a multilayer film.

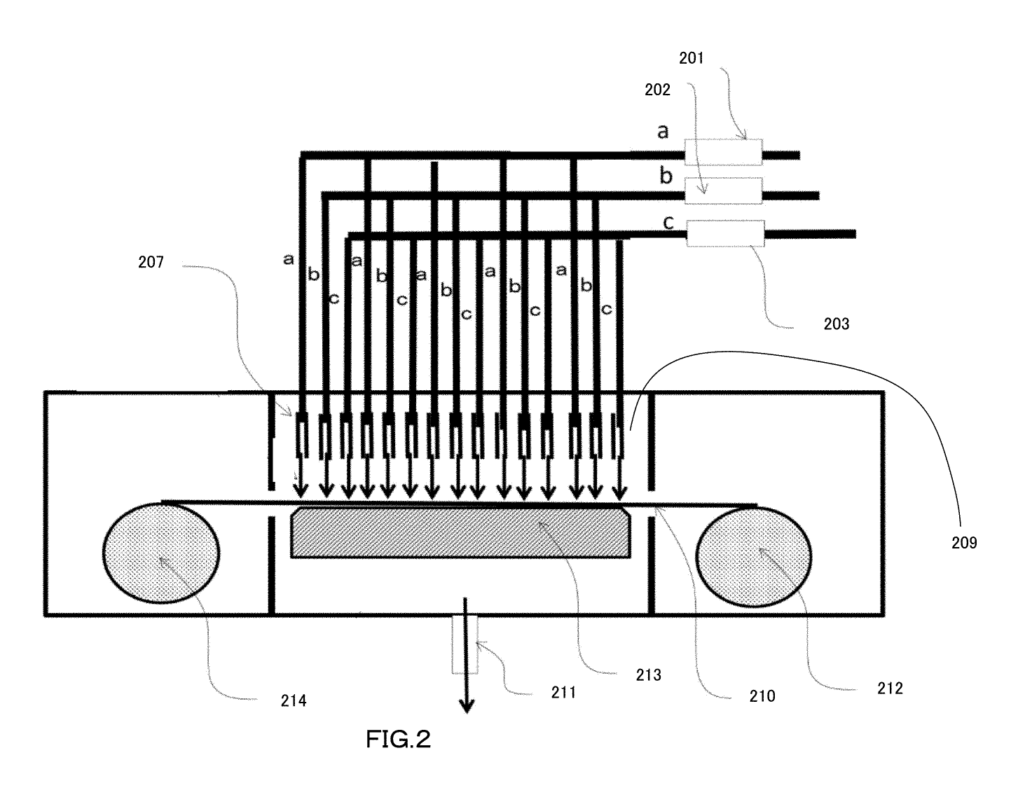

As a modification of the embodiment, as shown in FIG. 2, a film-forming apparatus may be configured.

The film-forming apparatus according to the modification of the embodiment, as shown in FIG. 2, includes gas instantaneously-heating mechanisms 201, 202, and 203, a guide 207, a film-forming chamber 209, a film-shaped substrate 210, an exhaust port 211, a rewinding drum 212, and a supply drum 214.

The film-forming apparatus according to the modification of the embodiment, as shown in FIG. 2, includes one film-forming chamber 209 to which the film-shaped substrate 210 is supplied from the film supply drum 214. The film-shaped substrate 210 passes over a film support table 213 and is collected by the rewinding drum 212 which rolls up a film. At this time, the reaction sets S for the generated gases a, b, and c are installed in a multiple stage over the film-shaped substrate 210, and the generated gases a, b, and c are supplied and brought into contact with the film-shaped substrate 210 to form a film. The number of reaction sets S can be freely designed depending on a desired film thickness.

### <Configuration of Gas Instantaneously-Heating Mechanism>

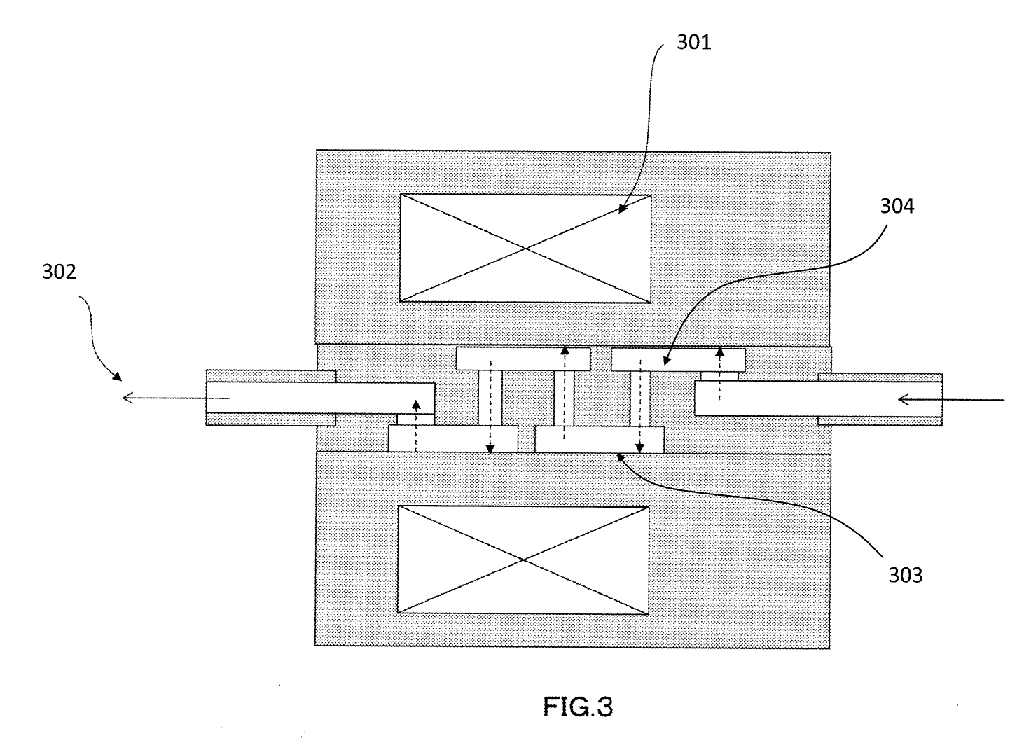

A schematic configuration of a gas instantaneously-heating mechanism according to the embodiment, as shown in FIG. 3, includes an electric heater 301 which surrounds a flow path 304 for a source gas defined by a flow path wall 303, and a gas 302 obtained by heating a source gas is discharged.

<Operation of the Embodiment>

Since active molecular species have a structure depending on a temperature of the gas instantaneously-heating mechanism, when a heating temperature is changed, the structure of generated gas molecular species related to a reaction will change. The structure of the source gas molecules does not change at a predetermined temperature or lower.

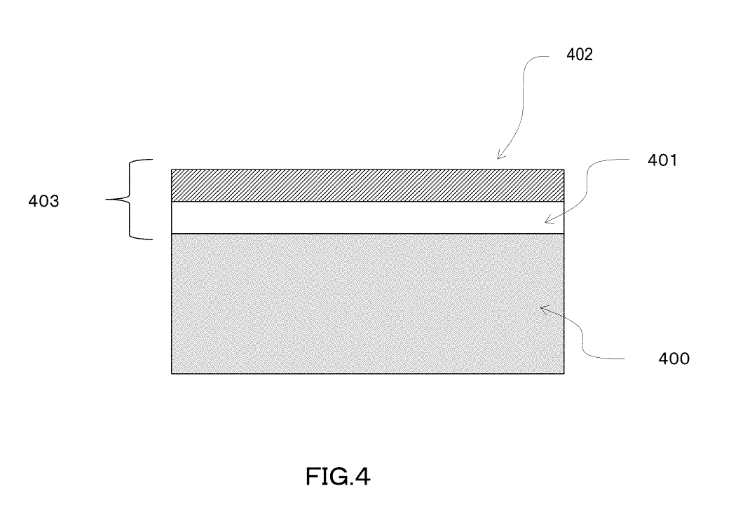

Thus, when a film is formed at heating temperatures varying in two steps, i.e., a heating temperature higher than the predetermined temperature and a heating temperature lower than the predetermined temperature, as shown in FIG. 4, a multilayer film 403 composed of a first compound film 401 and a second compound film 402 having different compositions, composition ratios, or structures containing a common constituent element can be formed.

For example, when the heating temperature is set to a low temperature, the formed first compound film 401 contains the same constituent elements as those at a high temperature and has a composition ratio different from that at the high temperature, or easily becomes a flexible film containing different bonding species. The first compound film 401 having a flexible structure is formed as an intermediate layer at a low heating temperature, and the second compound film 402 having a dense stable structure is grown by molecular species heated to a high temperature to form the compound multilayer film 403.

Since this stacked layer film 403 includes the first compound film 401 as a flexible intermediate layer, the multilayer structure 403 is not easily cracked. As multilayer films have different bonding species, different structures, or different composition ratios, they are able to have characteristics which cannot be obtained by a single layer. More specifically, a multilayer film in which two-layered grown films having different composition ratios are repeatedly formed, or a multilayer film in which films are made of different composition elements and heated in at least two steps at temperatures variation within a predetermined temperature range to change characteristics can also be designed.

In general, although a film having a dense structure easily prevents a gas from passing through the film, the film is easily cracked. A dense film having mechanical characteristics different from those of a substrate is easily peeled. For this reason, according to a multilayer film obtained by growing intermediate layers having different characteristics, this issue can be solved.

In the embodiment, the multilayer film is a compound film including the first compound film 401 and the second compound film 402 containing at least one element of hydrogen, oxygen, nitrogen, carbon, silicon, aluminum, gallium, titanium, zinc, indium, and magnesium.

The first compound film 401 may have a thickness thinner than that of the second compound film 402, and may be constituted by not only a single layer. Furthermore, the first compound film 401 may be a film having a composition gradient. In addition, when there is a chemical with which the substrate material reacts to improve adhesive force, the substrate surface may be treated with the chemical to modify the structure or bonding species of the surface, and the treated surface may be regarded as the first compound film 401.

In the embodiment, the temperature of the gas instantaneously-heating mechanism for source gas is changed within a set temperature range to form the first compound film 401 and the second compound film 402.

In the embodiment, the surface of a flow path in the gas instantaneously-heating mechanism for source gas is made of metal containing at least one element of ruthenium, nickel, platinum, iron, chromium, aluminum, and tantalum.

In the embodiment, the heating temperature of the gas instantaneously-heating mechanism for source gas ranges from room temperature to 900° C.

In order to make the first compound film 401 a high adhesive flexible layer, it is known that a composition design which supplies a source gas without heating purposely the source gas not to let the bonding species of the formed first compound film 401 be only stable bonding species. When this composition design is used, a source gas containing a metal element and water are alternatively supplied onto the substrate surface and caused to react with each other so as to make it possible to form a metal oxide film.

At this time, a design which grows the first compound film 401 keeping the gas instantaneously-heating mechanism at room temperature, and forms the second compound film 402 grown at a high temperature on the first compound film 401 achieves to obtain a multilayer film with high adhesion, resulting to prevent being cracked. On the other hand, to set the temperature of the gas instantaneously-heating mechanism to 900° C. or higher is practically improper because, when the gas instantaneously-heating mechanism is made of stainless steel, the surface reacts with hydrogen, water, and an ammonia source gas to make it impossible to maintain the material composition for a long time.

In the embodiment, a substrate 400 moves.

As shown in FIG. 1, two reaction sets are equipped, one for the generated gases a and b and the other for the generated gases c and d are defined as S1 and S2, respectively. A required number of reaction sets for generated gas are installed depending on the number of kinds of laminated films.

The first compound film 401 is formed by the reaction set S1, and the second compound film 402 is formed by the reaction set S2 to form the laminated film 403.

In the case in FIG. 1, since the number of kinds of multilayer films is two, the two reaction sets S1 and S2 are equipped. The generated gases 114 (a, b, c, and d) are introduced to the film-shaped substrates 117 placed in the film-forming chambers 115 and 116 through the guides 113, brought into contact with the film-shaped substrates 117, and exhausted from the exhaust ports 118 and 119, respectively.

The source gases A, B, C, and D, the heating temperatures Ta, Tb, Tc, and Td, and flow rates of the gases can be freely designed, and the source gases A, B, C, and D can be introduced according to time programming. The source gases A and B reacting with each other and the source gases C and D reacting with each other may be supplied at the different time, may be supplied at times which partially overlap, or may be supplied at the same time.

In the embodiment, the material of the substrate is glass, silicon wafer, plastic, or carbon. The substrate may be planar, curved, or cylindrical. When the material is plastic, a screw or a gear may be machined in the substrate.

In the embodiment, the substrate is an organic EL device, a liquid crystal device, a solar battery, or a device substrate on which patterns are formed. These devices are deteriorated by oxidization and moisture absorption. In order to prevent this, the device must be covered with a film-shaped substrate on which a multilayer film through which oxygen or water cannot pass is grown.

As described above, according to the embodiment, the source gas is heated to a high temperature to change the molecular structure of the source gas so as to generate chemically active molecular species. The active molecular species reacting with each other are introduced to the substrate surface and brought into contact with the substrate surface to make it possible to form a film on the surface of the substrate kept at a temperature lower than the temperature of the instantaneously-heating mechanism for source gas.

At this time, the use of different heating temperatures and the gases of different compositions make it possible to grow stacked films having different characteristics. In this manner, a high adhesive film with high flexibility and a dense film having a dense structure are formed on a substrate surface kept at a low temperature successfully. The dense film adheres to the substrate with the adhesive film, resulting low possibility of cracking and peeling

The temperature of the gas instantaneously-heating mechanism can be arbitrarily set. For this reason, a multilayer film can be grown controlling its film characteristics, independent from the temperature of the substrate. Furthermore, by selecting a kind of source gas and a catalytic metal element of the flow path, it is possible to design the temperature of the gas instantaneously-heating mechanism for source gas depending on desired generated molecular species.

Furthermore, a laminated film having two kinds of compositions can also be grown from different source gases. As examples of combinations with the first compound films and the second compound films, a laminated film composed of high adhesive aluminum oxide and a silicon oxide film, a laminated film composed of high adhesive aluminum oxide and a silicon nitride film having excellent water barrier property, and the like are conceived.

Multilayer films composed of various kinds of first compound films and second compound films can be designed. A multilayer film of aluminum oxide obtained by reaction of active molecular species of water and trimethyl aluminum (TMA) will be described in Example 1.

When water serving as an oxidizer and titanium tetrachloride which is one of titanium chloride are used as source gases, a titanium oxide film can be formed. When ammonia is decomposed by being heated at a predetermined temperature or higher, e.g., 600° C. to generate active molecular species NH₂.

When ammonia is used as a material for nitridization and combined with titanium tetrachloride, a film of titanium nitride TiN can be formed.

When an organic source material of silicon or a silicon chloride gas and ammonia are used as source materials, a silicon nitride film can be formed.

A combination of gallium chloride GaCl₃ and ammonia allows a film of gallium nitride to be formed.

The above is an example of combinations of elements. Combinations of the temperatures of the gas instantaneously-heating mechanism and source gas elements allow a composition or a composition ratio of a laminated film of the first compound film and the second compound film to be freely designed.

A combination of a plurality of generated molecular species allows a multilayer film of a compound having an arbitrary composition to be formed.

More specifically, a film of a binary compound can be formed at a low temperature, i.e., room temperature, for example, when generated molecular species of a source material containing a metal element and generated molecular species containing an element of an oxidizer are introduced and sprayed on the substrate surface alternately. A temperature at which active molecular species are generated is controlled and set within the range of room temperature to 900° C. depending on kinds of source gases. When the source gas is brought into contact with ruthenium or nickel serving as a catalytic element at a temperature controlled for ruthenium or nickel, the source gas decomposes to generate active molecular species. Active molecular species have certain lifetimes without being immediately returned to the original stable molecules, reach the substrate surface remaining as the active molecular species, react with each other on the substrate surface to generate a compound film.

Active molecular species of a source material of an organic metal gas containing silicon and a metal element such as aluminum, zirconium, magnesium, hafnium, gallium, zinc, titanium, or indium are oxidized to generate high energy, and react violently with active molecular species of a source material of water containing an oxygen element. Gases reacting with these metal source gases include water, reducing gases such as hydrogen and ammonia, and a mixed gas thereof. A combination of source gases can be freely designed.

A substrate is enabled to move relative to a place where the substrate is in contact with the generated gas.

More specifically, generated molecular species a of the source gas A instantaneously heated at the temperature Ta and generated molecular species b of the source gas B instantaneously heated at the temperature Tb are sprayed from a set of an equipped guide, and the generated molecular species a and b react with each other on the substrate to form a compound film. The compound film is denoted by an AB film by using signs here.

Generated molecular species c of the source gas C obtained by instantaneous heating at the temperature Tc and generated molecular species d of source gas D obtained by instantaneous heating at the temperature Td are sprayed from an equipped guide to form a CD film as a compound film.

When the substrate moves under the prepared guide a multilayer film composed of the AB film and the CD film is obtained on the substrate surface. At this time, when the substrate is continuous film shaped, a multilayer film composed of the compound AB film and the compound CD film can be continuously formed on the film-shaped substrate. In this case, when A=C and B=D are satisfied, the multilayer film is a stacked film composed of a compound AB film 1 and a compound AB film 2 which are different from each other.

A substrate material can be freely selected from glass, silicon wafer, plastic, and carbon. When the substrate is plastic, the film-shaped substrate moves such that the film-shaped substrate is supplied from the supply drum 121 and rewound by the rewinding drum 120.

Since these materials except for glass have small adsorption energy when the active molecular species are adsorbed, an adsorption density is low, and a chemical reaction is hard to occur on the substrate surface. When a source gas generating molecular species which are easily adsorbed is selected, the compound film is formed on the substrate surface. In this case, the compound film 1 is an adsorption layer of active molecular species. When the adsorption layer having increasing adsorption energy is designed, a multilayer film having high adhesion to the substrate can be designed.

A film can be formed on an organic EL device, a liquid-crystal device, a solar battery, or a device substrate on which photoresist patterns are formed.

A display device typified by an organic EL is deteriorated due to oxidization or moisture absorption. This prevents the display device from being practically used with guarantee the lifetime of the display device. For this reason, there is an issue in that a protective thin film of a moisture-resistant material cannot formed on the surface of the substrate on which the device is formed while keeping the large area substrate at a low temperature.

At present, vacuum sputtering of a silicon oxide film is only a method. However, a manufacturing cost is high to inhibit a large-sized organic EL display from being practically used. In order to secure long-term reliability of a solar battery, the production cost of the solar battery increases.

A silicon oxide film or the like of a mask material having dry-etching resistance is grown on the photoresist pattern. However, this is an expensive process because the process uses a plasma CVD method. However, since the film-forming method according to the embodiment is a film-forming method performed by only heat without using a plasma process, an inexpensive process can be achieved.

### First Example

This example describes an example in which the film-forming apparatus shown in FIG. 1 grows, as the compound stacked film 403, the multilayer film 403 composed of the first compound film 401 of aluminum oxide and a second compound film 402 of aluminum oxide on the surface of the plastic substrate 400.

As the source gases A and C, a mixed gas of source water bubbled with nitrogen and nitrogen carriers is used. As the source gases B and D, a mixed gas of source TMA bubbled with nitrogen and nitrogen carriers is used.

A program which supplies the source gases A and B and the source gases C and D in periods of time which do not overlap is used. The source gases are heated to the temperatures Ta, Tb, Tc, and Td by the gas instantaneously-heating mechanisms 105, 106, 107, and 108, respectively to emit the generated gases a, b, c, and d (109, 110, 111, and 112).

In this case, the temperature is set as follows, Ta=160° C., Tb=50° C., Tc=Td=160° C. The generated gas a (109) of water is in a cluster state in which water molecules are gathered, and the generated gas b (110) of the TMA is a dimer. The generated gas c (111) of water and the generated gas d (112) of TMA are molecular species of a monomer.

The generated gases a and b are introduced by pipes, blow out of the guides 113, and are brought into contact with the film-shaped substrate 117 of polyethylene terephthalate (PET) which is plastics. The generated gas a heated at 160° C. and the generated gas b heated at 50° C. are supplied through the two guides 113 to form the reaction set S1 which causes certain reaction.

In the case in FIG. 1, although the gases are supplied through the two guides, the number of guides can be freely designed according to the size.

Similarly, the generated gases c and d form the reaction set S2 to which the gases are supplied through two guides. Pressures of the film-forming chambers 115 and 116 were adjusted to reduced pressures of about 0.1 to 0.5 atmospheres and set.

In the film-forming chamber 115, the first compound film of aluminum oxide was formed on the substrate surface by surface reaction between the generated gas a heated at 160° C. and the generated gas b heated at 50° C. In the film-forming chamber 116, the second compound film of aluminum oxide was formed by surface reaction between the generated gases c and d heated at 160° C.

When the film-shaped substrate 117 of PET was moved, the film-shaped substrate 117 on which a multilayer film of the compounds of the first compound film and the second compound film were formed was obtained.

The compositions of the first compound film of aluminum oxide and the second compound film of aluminum oxide commonly include aluminum element Al and oxygen element O. When a difference between the compositions of the two elements were analyzed, a composition ratio of Al/O was larger in the second compound film than that in the first compound film.

In order to check the difference of degrees of adhesion between the substrate and the generated films, these films were independently grown on the film-shaped substrate 117, and the films were transformed. Although the first compound film was not easily cracked and peeled, the second compound film was relatively easily cracked and peeled.

Since those compositions were different, when elution of aluminum in water was analyzed, it was recognized that elution of aluminum from the first compound film was larger than that from the second compound film. In perfectly bonded aluminum oxide, aluminum is not eluted into water.

An aluminum oxide stack film composed of the first compound and the second compound according to this example was not easily peeled even though the substrate film is transformed, and elution of aluminum is suppressed. According to this, due to the presence of the first compound film, an aluminum oxide multilayer film which could not be cracked and peeled was obtained, moreover, the elution of element Al from this film was suppressed. In this manner, a film-shaped substrate of PET on which aluminum oxide was formed could be manufactured by the film-forming apparatus in FIG. 1.

### Second Example

In the first example, the constituent elements of the first compound film and the second compound film were oxygen and aluminum which were common. The second example is an example of a multilayer film composed of the films in which at least one of constituent elements is different.

Aluminum oxide was selected as the first compound film, and a silicon oxide film was selected as the second compound film. As the source gases A and C, a mixed gas of a gas obtained by bubbling water with nitrogen and nitrogen carriers was used.

As the source gas B, a mixed gas of trimethyl aluminum (TMA) bubbled with nitrogen and nitrogen carriers was used. As the source gas D, a mixed gas of silicon tetrachloride bubbled with nitrogen and nitrogen carriers was used.

The source gases A and B and the source gases C and D were supplied by a program having periods of time which do not overlap. The source gases were heated to the temperatures Ta, Tb, Tc, and Td by the gas instantaneously-heating mechanisms 105, 106, 107, and 108, respectively to emit the generated gases a, b, c, and d (109, 110, 111, and 112).

In this case, the temperature is set as follows, Ta=160° C., Tb=50° C., and Tc=Td=600° C.

The generated gases a and b are introduced by pipes, blow out of the guides 113, and are brought into contact with the film-shaped substrate 117 of PET which is plastics. The reaction set S1 is formed with the heated generated gases a and b, which are supplied by the two guides 113 to react each other.

In the same manner as described above, the generated gases c and d form the reaction set S2 to which those gases are supplied from two guides. Pressures of the film-forming chambers 115 and 116 were adjusted to reduced pressures of about 0.1 to 0.5 atmospheres and set.

In the film-forming chamber 115, a first compound film of aluminum oxide was formed by reaction between the generated gas a heated at 160° C. and the generated gas b heated at 50° C. In the film-forming chamber 116, a second compound film of silicon oxide was formed by reaction between the generated gases c and d heated at 600° C.

When the film-shaped substrate 117 of PET was moved, the film-shaped substrate 117 on which a multilayer film of the first compound film and the second compound film was formed was obtained. The compositions of the first compound film and the second compound film commonly contain oxygen element O.

The first compound film of aluminum oxide is not easily peeled from the film-shaped substrate of PET. The second compound film of silicon oxide is easily peeled from the PET film when it is formed singularly. However, this multilayer film is not easily peeled from the film-shaped substrate of PET because the multilayer film has the first compound film which is not easily peeled. For this reason, the film-forming apparatus shown in FIG. 1 could manufacture the film-shaped substrate 117 of PET formed with multilayer film by growing aluminum oxide and a silicon oxide.

### Third Example

In the third example, an aluminum oxide film was selected as the first compound film, and an aluminum nitride film was selected as the second compound film.

As the source gas A, a mixed gas of water bubbled with nitrogen and nitrogen carriers was used. As the source gases B and D, a mixed gas of trimethyl aluminum (TMA) bubbled with nitrogen and nitrogen carriers was used.

As the source gas C, a mixed gas of ammonia and nitrogen carriers was used.

The source gases A and B and the source gases C and D were supplied by a program having periods of time which do not overlap. The source gases were heated to the temperatures Ta, Tb, Tc, and Td by the gas instantaneously-heating mechanisms 105, 106, 107, and 108, respectively to emit the generated gases a, b, c, and d (109, 110, 111, and 112).

In this case, Ta=160° C., Tb=50° C., the heating temperature Tc of a source gas of ammonia=600° C., and the heating temperature Td of a source gas of TMA=300° C. are used.

The generated gases a and b are introduced by pipes, blow out of the guides 113, and are brought into contact with the film-shaped substrate 117 of PET which is plastics. The heated generated gases a and b are supplied by the two guides 113 to form a first compound film which is an aluminum oxide film.

The generated gas c is obtained by decomposing ammonia at 600° C. and it is estimated that this gas contains molecular species NH₂ or the like having nitridization capability. Pressures of the film-forming chambers 115 and 116 were adjusted to reduced pressures of about 0.1 to 0.5 atmospheres and set.

In the film-forming chamber 115, the first compound film of aluminum oxide was formed by reaction between the generated gases a and b. In the film-forming chamber 116, the second compound film of aluminum nitride was formed by reaction between the generated gases c and d.

When the film-shaped substrate 117 of PET was moved, the film-shaped substrate on which a multilayer film of the first compound film and the second compound film was formed was obtained. The compositions of the first compound film of aluminum oxide and the second compound film of aluminum nitride commonly includes aluminum Al.

The first compound film of aluminum oxide is not easily peeled from the film-shaped substrate of PET. The second compound film of aluminum nitride is easily peeled from the PET film when it is formed singularly. The multilayer film is not easily peeled from the film-shaped substrate of PET because the multilayer film has the first compound film which is not easily peeled. For this reason, the film-forming apparatus shown in FIG. 1 could manufacture the film-shaped substrate of PET formed with aluminum oxide and an aluminum nitride film.

The embodiment of the present invention has been described in detail with reference to the accompanying drawings. However, a concrete configuration is not limited to that in the embodiment, and the invention also includes a design or the like without departing from the spirit and scope of the invention.

### REFERENCE SIGNS LIST

101: source gas A
102: source gas B
103: source gas C
104: source gas D
105: gas instantaneously-heating mechanism
106: gas instantaneously-heating mechanism
107: gas instantaneously-heating mechanism
108: gas instantaneously-heating mechanism
109: generated gas a
110: generated gas b
111: generated gas c
112: generated gas d
113: guide
114: introduced generated gas
S1: reaction set
S2: reaction set
115: film-forming chamber
116: film-forming chamber
117: film-shaped substrate
118: exhaust port
119: exhaust port
120: rewinding drum
121: supply drum
201: gas instantaneously-heating mechanism
202: gas instantaneously-heating mechanism
203: gas instantaneously-heating mechanism
207: guide
209: film-forming chamber
210: film-shaped substrate
211: exhaust port
212: rewinding drum
213: support table
214: supply drum
301: electric heater
302: heated gas
400: substrate
401: first compound film
402: second compound film
403: multilayer film

What is claimed is:

1. A film-forming method using a film-forming apparatus providing a plurality of heating mechanisms, each heating mechanism including a flow path defined by a flow path wall in which a source gas collides with the flow path wall to heat the source gas by heat exchange between the source gas and the flow path wall, thereby generating chemically active gas molecular species, and a gas outlet connected to a guide through a pipe, comprising the steps of:
introducing at least two kinds of the gas molecular species generated by heating by the plurality of heating mechanisms independently and blowing out at least two kinds of the gas molecular species through the guides to bring into contact with a substrate kept at a temperature lower than a heating temperature of the heating mechanisms to form a first compound film; and
forming a second compound film containing at least one element of elements contained in the first compound film on the first compound film to form a multilayer film including at least the first compound film and the second compound film on the substrate.

2. The film-forming method according to claim 1, wherein
the heating mechanism includes the flow path wall made of a metal material containing an element having a catalytic function.

3. The film-forming method according to claim 1, wherein
the first compound film and the second compound film are compound films containing at least one of elements including hydrogen, oxygen, nitrogen, carbon, silicon, aluminum, gallium, titanium, zinc, indium, and magnesium.

4. The film-forming method according to claim 1, wherein
the first compound film and the second compound film are formed while a temperature of the heating mechanism is changed within a set temperature range.

5. The film-forming method according to claim 2, wherein
the flow path wall of the heating mechanism is made of a metal containing at least one of elements including ruthenium, nickel, platinum, iron, chromium, aluminum, and tantalum.

6. The film-forming method according to claim 1, wherein
the heating temperature of the heating mechanism ranges from room temperature to 900° C.

7. The film-forming method according to claim 6, wherein the substrate moves.

8. The film-forming method according to claim 1, wherein
a material of the substrate on which the multilayer film is formed is at least one of materials including glass, silicon wafer, plastic, and carbon.

9. The film-forming method according to claim 1, wherein
the substrate is an organic EL device, a liquid crystal device, a solar battery, or a device substrate on which patterns are formed.
